(19) United States
(12) Patent Application Publication
(10) Pub. No.: US 2024/0250661 A1
(43) Pub. Date: Jul. 25, 2024

(54) ACOUSTIC WAVE DEVICE AND METHOD OF MANUFACTURING ACOUSTIC WAVE DEVICE

(71) Applicant: Murata Manufacturing Co., Ltd., Nagaokakyo-shi (JP)

(72) Inventors: Takashi YAMANE, Nagaokakyo-shi (JP); Hisashi YAMAZAKI, Nagaokakyo-shi (JP)

(21) Appl. No.: 18/627,897

(22) Filed: Apr. 5, 2024

Related U.S. Application Data
(63) Continuation of application No. PCT/JP2022/037495, filed on Oct. 6, 2022.
(60) Provisional application No. 63/253,593, filed on Oct. 8, 2021.

(51) Int. Cl. H03H 9/10; H03H 3/02; H03H 9/02; H03H 9/05; H03H 9/13; H03H 9/17

(52) U.S. Cl. CPC H03H 9/105; H03H 3/02; H03H 9/02031; H03H 9/02157; H03H 9/02228; H03H 9/0523; H03H 9/13; H03H 9/173; H03H 9/176; H03H 2003/021

(57) ABSTRACT

An acoustic wave device includes a first substrate, a piezoelectric layer including one main surface facing the first substrate and another main surface facing a direction opposite to the one main surface, a functional electrode on at least one of the one and the other main surfaces, and a second substrate including a first main surface facing the other main surface of the piezoelectric layer, a second main surface facing a direction opposite to the first main surface, and a through-hole penetrating from the first main surface to the second main surface. An angle at which a side surface of the through-hole is inclined from the second main surface toward the first main surface is equal to or more than about 0° and equal to or less than about 5° based on a normal line with respect to the second main surface.

### CROSS REFERENCE TO RELATED APPLICATIONS

This application claims the benefit of priority to Provisional Application No. 63/253,593 filed on Oct. 8, 2021 and is a Continuation Application of PCT Application No. PCT/JP2022/037495 filed on Oct. 6, 2022. The entire contents of each application are hereby incorporated herein by reference.

### BACKGROUND OF THE INVENTION

### 1. Field of the Invention

The present disclosure relates to acoustic wave devices each including a piezoelectric layer including lithium niobate or lithium tantalate, and methods of manufacturing acoustic wave devices.

### 2. Description of the Related Art

Japanese Unexamined Patent Application Publication No. 2012-257019 describes an acoustic wave device.

In the case where the acoustic wave device is in wafer-level packaging by covering an electrode with a substrate (second substrate), a through-via penetrating the substrate (second substrate) is provided. The substrate (second substrate) has a first surface facing the electrode and a second surface facing the opposite side. Conventionally, a through-hole is formed from the second surface by dry etching. The through-hole is tapered such that the hole diameter decreases from the second surface towards the first surface. That is, the opening of the through-hole formed in the second surface is larger than the opening of the through-hole formed in the first surface. Therefore, in the second surface of the substrate (second substrate), the area occupied by the through-via (area where the bump is placed) is increased in size, and the layout of the second surface of the substrate is impaired.

### SUMMARY OF THE INVENTION

Example embodiments of the present invention provide acoustic wave devices in each of which an area occupied by a through-via on a second surface of a substrate (second substrate) is reduced in size, and methods for manufacturing such acoustic wave devices.

An acoustic wave device according to an example embodiment of the present invention includes a first substrate, a piezoelectric layer including one main surface facing the first substrate in a thickness direction of the first substrate and another main surface facing a direction opposite to the one main surface in the thickness direction, a functional electrode on at least one of the one main surface and the other main surface of the piezoelectric layer, and a second substrate including a first main surface facing the other main surface of the piezoelectric layer, a second main surface facing a direction opposite to the first main surface in the thickness direction, and a through-hole penetrating from the first main surface to the second main surface. An angle at which a side surface of the through-hole is inclined from the second main surface toward the first main surface is equal to or more than about 0° and equal to or less than about 5° based on a normal line with respect to the second main surface.

A method of manufacturing an acoustic wave device according to an example embodiment of the present invention includes a through-hole forming step of forming a through-hole in an object. The object includes a first substrate, a piezoelectric layer including one main surface facing the first substrate in a thickness direction of the first substrate and another main surface facing a direction opposite to the one main surface in the thickness direction, a functional electrode on at least one of the one main surface and the other main surface of the piezoelectric layer, a second substrate including a first main surface facing the other main surface of the piezoelectric layer and a second main surface facing a direction opposite to the first main surface in the thickness direction, and a wiring layer between the piezoelectric layer and the second substrate and bonding the piezoelectric layer and the second substrate. In the through-hole forming step, a through-hole is formed in the second main surface of the second substrate by repeatedly performing a step of performing isotropic etching, a step of depositing a protective film on a side surface and a bottom surface of a hole formed by the isotropic etching, and a step of etching the protective film on the bottom surface.

According to each of example embodiments of the present invention, an area occupied by a through-via on a second surface of a substrate (second substrate) is reduced in size. Therefore, the layout property of the second surface of the substrate is improved.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1A is a perspective view of an acoustic wave device of an example embodiment of the present invention.

FIG. 1B is a plan view illustrating the structure of electrodes of an example embodiment of the present invention.

FIG. 2 is a cross-sectional view of a portion taken along line II-II of FIG. 1A.

FIG. 3A is a schematic cross-sectional view for explaining a Lamb wave propagating through a piezoelectric layer of a comparative example.

FIG. 3B is a schematic cross-sectional view for explaining a bulk wave in a first-order thickness-shear mode propagating through a piezoelectric layer of an example embodiment of the present invention.

FIG. 4 is a schematic cross-sectional view for explaining an amplitude direction of a bulk wave in a first-order thickness-shear mode propagating through a piezoelectric layer of an example embodiment of the present invention.

FIG. 5 is an explanatory diagram illustrating an example of resonance characteristics of an acoustic wave device of an example embodiment of the present invention.

FIG. 6 is an explanatory diagram illustrating a relationship between d/2p and a fractional bandwidth as a resonator in an acoustic wave device of an example embodiment of the present invention, when p is a center-to-center distance between adjacent electrodes to each other or the average distance of the center-to-center distance, and d is the average thickness of the piezoelectric layer.

FIG. 7 is a plan view illustrating an example in which a pair of electrodes are provided in an acoustic wave device of an example embodiment of the present invention.

FIG. 8 is a reference diagram illustrating an example of resonance characteristics of an acoustic wave device of an example embodiment of the present invention.

FIG. 9 is a diagram illustrating a relationship between the fractional bandwidth and a phase rotation amount of spurious impedance normalized by about 180 degrees as a magnitude of spurious emission when a large number of acoustic wave resonators are provided according to an example embodiment of the present invention.

FIG. 10 is a diagram illustrating a relationship between d/2p, a metallization ratio MR, and the fractional bandwidth.

FIG. 11 is a diagram illustrating a map of a fractional bandwidth with respect to the Euler angles (0°, θ, ψ) of LiNbO₃ when d/p approaches 0 as much as possible.

FIG. 12 is a partially cutaway perspective view of an acoustic wave device of a modification of an example embodiment of the present invention.

FIG. 13 is a schematic view illustrating the configuration of an acoustic wave device of an example embodiment of the present invention.

FIG. 14 is an enlarged view of a range surrounded by a frame line XIV in FIG. 13.

FIG. 15 is an enlarged view of a range surrounded by a frame line XV in FIG. 14.

FIG. 16 is a cross-sectional view illustrating an intermediate product after a bonding step of an example embodiment of the present invention.

FIG. 17 is a cross-sectional view illustrating an intermediate product after a through-hole forming step of an example embodiment of the present invention.

FIG. 18 is a cross-sectional view illustrating an intermediate product after an insulating film forming step of an example embodiment of the present invention.

FIG. 19 is a cross-sectional view illustrating an intermediate product after a dry etching step of an example embodiment of the present invention.

FIG. 20 is a cross-sectional view illustrating an intermediate product after a seed layer laminating/resist film forming/plate processing step of an example embodiment of the present invention.

FIG. 21 is a cross-sectional view illustrating an intermediate product after a resist film removing/window forming step of an example embodiment of the present invention.

FIG. 22 is a cross-sectional view illustrating an intermediate product after a dicing step of an example embodiment of the present invention.

FIG. 23 is a cross-sectional view illustrating an intermediate product after soldering of an example embodiment of the present invention.

FIG. 24 is a cross-sectional view of an acoustic wave device after a polishing step of an example embodiment of the present invention.

FIG. 25 is a schematic view illustrating the configuration of an acoustic wave device according to a modification of an example embodiment of the present invention.

### DETAILED DESCRIPTION OF THE EXAMPLE EMBODIMENTS

Hereinafter, example embodiments of the present invention will be described in detail with reference to the drawings. The present disclosure is not limited to the example embodiments. Each example embodiment described in the present invention is merely an example, and in modifications and second and subsequent example embodiments in which partial replacement or combination of configurations is possible between different example embodiments, description of matters common to the first example embodiment will be omitted, and only different points will be described. In particular, the same or similar advantageous effects of similar configurations will not be described in each example embodiment.

### EXAMPLE EMBODIMENTS

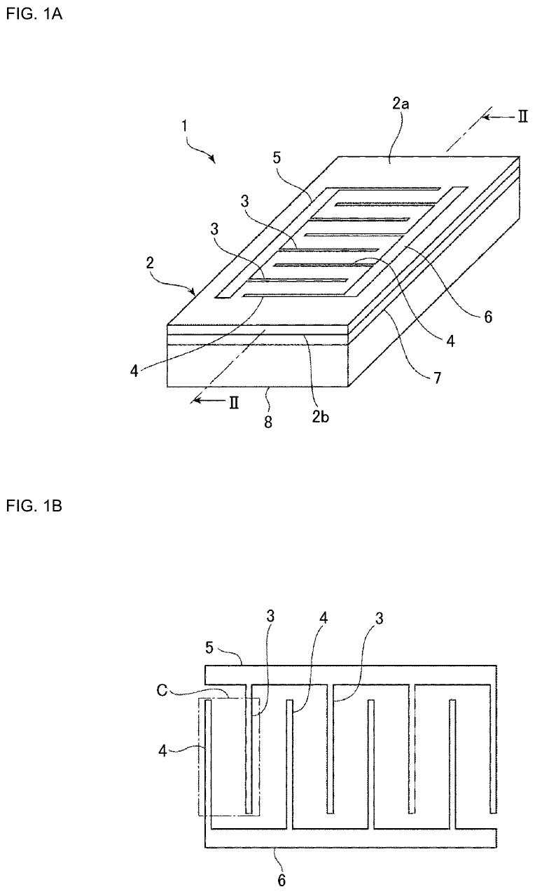

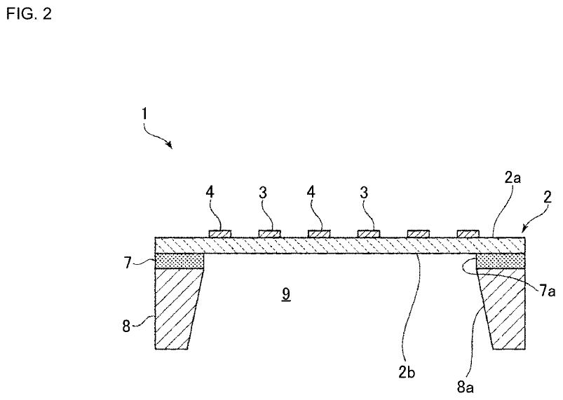

FIG. 1A is a perspective view of an acoustic wave device of an example embodiment of the present invention. FIG. 1B is a plan view illustrating the structure of electrodes of the present example embodiment. FIG. 2 is a cross-sectional view of a portion taken along line II-II of FIG. 1A. First, a basic configuration of the acoustic wave device will be described. An acoustic wave device of the present example embodiment includes a piezoelectric layer made of lithium niobate or lithium tantalate, for example, and a first electrode and a second electrode facing each other in a direction intersecting a thickness direction of the piezoelectric layer. The bulk wave in a first-order thickness-shear mode is used in the acoustic wave device. Additionally, the first electrode and the second electrode are adjacent to each other, and when the thickness of the piezoelectric layer is defined as d and the center-to-center distance between the first electrode and the second electrode is defined as p, d/p is, for example, equal to or less than about 0.5. Thus, the acoustic wave device can have a high Q value even when the size thereof is reduced. In addition, the acoustic wave device uses, for example, a Lamb wave as a plate wave. Thus, resonance characteristics by the Lamb wave can be obtained.

In detail, as illustrated in FIGS. 1A, 1B, and FIG. 2, an acoustic wave device 1 includes a piezoelectric layer 2 made of LiNbO₃, for example. The piezoelectric layer 2 may be made of LiTaO₃, for example. The cut angle of LiNbO₃ and LiTaO₃ is Z-cut in the present example embodiment, but may be rotated Y-cut or X-cut. Preferably, for example, a propagation orientation of Y propagation and X propagation about ±30° is preferable. The thickness of the piezoelectric layers 2 is not particularly limited, but is, for example, preferably equal to or more than about 50 nm and equal to or less than about 1000 nm in order to effectively excite the first-order thickness-shear mode. The piezoelectric layer 2 includes another main surface 2a and one main surface 2b facing each other. An electrode 3 and an electrode 4 are provided on the other main surface 2a.

Here, the electrode 3 is an example of a “first electrode”, and the electrode 4 is an example of a “second electrode”. In FIGS. 1A and 1B, the plurality of electrodes 3 include a plurality of first electrode fingers connected to a first busbar 5. The plurality of electrodes 4 include a plurality of second electrode fingers connected to a second busbar 6. The plurality of electrodes 3 and the plurality of electrodes 4 are interdigitated with each other.

The electrode 3 and the electrode 4 have a rectangular shape and a length direction. The electrode 3 and the electrode 4 adjacent to the electrode 3 face each other in a direction orthogonal to the length direction. The electrodes 3 and 4 and the first and second busbars 5 and 6 constitute interdigital transducer (IDT) electrodes.

The length direction of the electrodes 3 and 4 and the direction orthogonal or substantially orthogonal to the length direction of the electrodes 3 and 4 are each directions intersecting the thickness direction of the piezoelectric layer 2. Therefore, it can be said that the electrode 3 and the electrode 4 adjacent to the electrode 3 face each other in a direction intersecting the thickness direction of the piezoelectric layer 2. In addition, the length direction of the electrodes 3 and 4 may be exchanged with the direction orthogonal or substantially orthogonal to the length direction of the electrodes 3 and 4 illustrated in FIGS. 1A and 1B. That is, in FIGS. 1A and 1B, the electrodes 3 and 4 may extend in a direction in which the first busbar 5 and the second busbar 6 extend. In this case, the first busbar 5 and the second busbar 6 extend in a direction in which the electrodes 3 and 4 extend in FIGS. 1A and 1B.

A plurality of pairs of structures each including the electrode 3 connected to one potential and the electrode 4 connected to the other potential adjacent to each other is provided in a direction orthogonal or substantially orthogonal to the length direction of the electrode 3 and the electrode 4. Here, the electrode 3 and the electrode 4 being adjacent to each other does not mean the case where the electrode 3 and the electrode 4 are arranged so as to be in direct contact with each other, but means the case where the electrode 3 and the electrode 4 are arranged with a gap therebetween. In addition, when the electrode 3 and the electrode 4 are adjacent to each other, no electrode connected to a hot electrode or a ground electrode, including the other electrodes 3 and 4, is arranged between the electrode 3 and the electrode 4. The number of pairs is not necessary an integer pair, and may be 1.5 pairs, 2.5 pairs, or the like.

The center-to-center distance between the electrode 3 and the electrode 4, that is, the pitch is, for example, preferably in the range of equal to or more than about 1 μm and equal to or less than about 10 μm. In addition, the center-to-center distance between the electrode 3 and the electrode 4 is a distance between the center of the width dimension of the electrode 3 in the direction orthogonal to the length direction of the electrode 3 and the center of the width dimension of the electrode 4 in the direction orthogonal or substantially orthogonal to the length direction of the electrode 4.

Further, when at least one of the electrode 3 and the electrode 4 is plural in number (there are 1.5 or more pairs of electrode sets when the electrodes 3 and 4 are provided as a pair of electrode sets), the center-to-center distance between the electrode 3 and the electrode 4 refers to the average value of the center-to-center distances between the adjacent electrodes 3 and 4 among the 1.5 or more pairs of electrodes 3 and 4.

In addition, the widths of the electrodes 3 and 4, that is, the dimensions of the electrodes 3 and 4 in a facing direction are, for example, preferably in the range of equal to or more than about 150 nm and equal to or less than about 1000 nm. The center-to-center distance between the electrode 3 and the electrode 4 is a distance between the center of the dimension (width dimension) of the electrode 3 in the direction orthogonal or substantially orthogonal to the length direction of the electrode 3 and the center of the dimension (width dimension) of the electrode 4 in the direction orthogonal or substantially orthogonal to the length direction of the electrode 4.

Additionally, in the present example embodiment, since the Z-cut piezoelectric layer is used, the direction orthogonal or substantially orthogonal to the length direction of the electrode 3 and the electrode 4 is a direction orthogonal or substantially orthogonal to a polarization direction of the piezoelectric layer 2. This is not the case when a piezoelectric material having a different cut angle is used as the piezoelectric layer 2. Here, the term “orthogonal” is not limited to the case of being strictly orthogonal, and may be substantially orthogonal (the angle formed by the direction orthogonal to the length direction of the electrodes 3 and 4 and the polarization direction is, for example, about 90°±10°).

A support 8 is laminated on the one main surface 2b side of the piezoelectric layer 2 via an insulating layer 7. The insulating layer 7 and the support 8 have a frame shape, and include opening portions 7a and 8a as illustrated in FIG. 2. Thus, a cavity portion (air gap) 9 is formed.

The cavity portion 9 is provided so as not to hinder the vibration of an excitation region C of the piezoelectric layer 2. Therefore, the above support 8 is laminated on the one main surface 2b via the insulating layer 7 at a position not overlapping the portion where at least the pair of electrodes 3 and 4 are provided. The insulating layer 7 need not be provided. Therefore, the support 8 can be laminated directly or indirectly on the one main surface 2b of the piezoelectric layer 2.

The insulating layer 7 is made of silicon oxide, for example. However, in addition to silicon oxide, an appropriate insulating material such as, for example, silicon oxynitride or alumina can be used. The support 8 is made of Si, for example. The plane orientation of Si in the surface on the piezoelectric layer 2 side may be (100), (110), or (111). Preferably, Si having a high resistance of, for example, equal to or more than about 4 kΩ is used.

However, the support 8 may be made of an appropriate insulating material or semiconductor material. As the material of the support 8, for example, a piezoelectric material such as aluminum oxide, lithium tantalate, lithium niobate, or quartz, various ceramics such as alumina, magnesia, sapphire, silicon nitride, aluminum nitride, silicon carbide, zirconia, cordierite, mullite, steatite, or forsterite, a dielectric material such as diamond or glass, or a semiconductor such as gallium nitride can be used.

The plurality of electrodes 3 and 4, the first busbar 5, and the second busbar 6 described above are made of an appropriate metal or alloy such as, for example, Al or an AlCu alloy. In the present example embodiment, the electrodes 3 and 4, the first busbar 5, and the second busbar 6 have a structure including an Al film laminated on a Ti film. An adhesion layer other than the Ti film may be used.

During driving, an AC voltage is applied between the plurality of electrodes 3 and the plurality of electrodes 4. More specifically, an AC voltage is applied between the first busbar 5 and the second busbar 6. Thus, it is possible to obtain resonance characteristics using a bulk wave in the first-order thickness-shear mode excited in the piezoelectric layer 2.

Additionally, in the acoustic wave device 1, d/p is, for example, equal to or less than about 0.5, when d is the thickness of the piezoelectric layer 2, and p is the center-to-center distance between any adjacent electrodes 3 and 4 among the plurality of pairs of electrodes 3 and 4. Therefore, the above bulk wave of the first-order thickness-shear mode is effectively excited, and favorable resonance characteristics can be obtained. More preferably, for example, d/p is equal to or less than about 0.24, and in this case, even more favorable resonance characteristics can be obtained.

In the case where at least one of the electrodes 3 and 4 is plural in number as in the present example embodiment, that is, there are 1.5 or more pairs of electrodes 3 and 4 sets when the electrodes 3 and 4 are provided as a pair of electrode sets, the center-to-center distance p between the adjacent electrodes 3 and 4 is the average distance of the center-to-center distances between the respective adjacent electrodes 3 and 4.

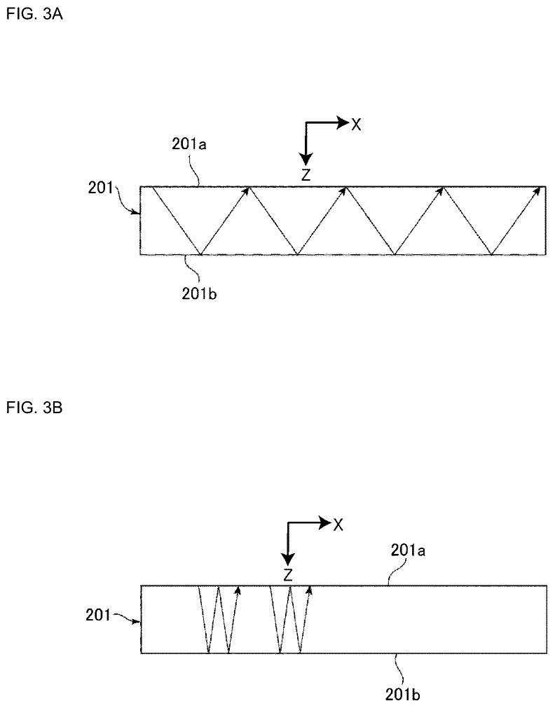

Since the acoustic wave device 1 of the present example embodiment has the above-described configuration, even when the number of pairs of the electrodes 3 and 4 is reduced in order to achieve miniaturization, the Q value is unlikely to be reduced. This is because the resonator does not require reflectors on both sides and has a small propagation loss. In addition, the reflector is not required because the bulk wave in the first-order thickness-shear mode is used. The difference between the Lamb wave used in the existing acoustic wave device and the bulk wave in the first-order thickness-shear mode will be described with reference to FIGS. 3A and 3B.

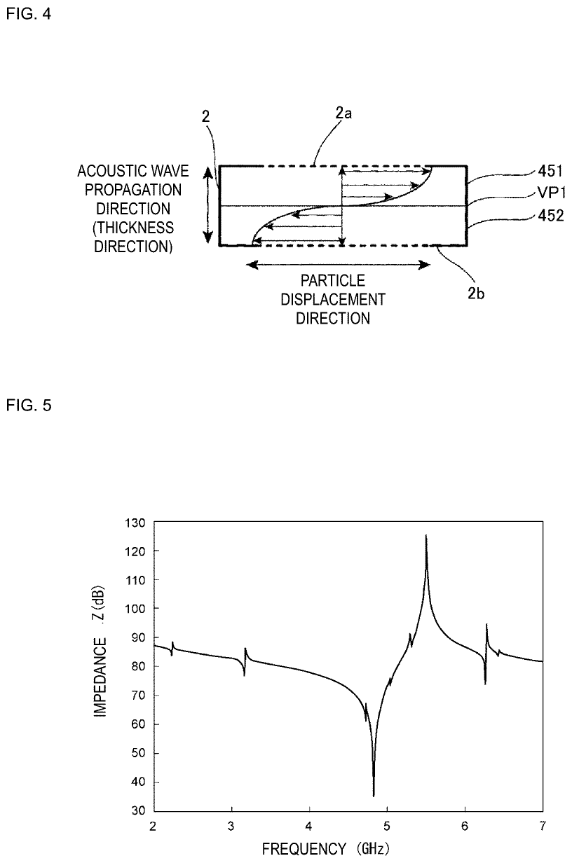

FIG. 3A is a schematic cross-sectional view for explaining a Lamb wave propagating through the piezoelectric layer of a comparative example. FIG. 3B is a schematic cross-sectional view for explaining a bulk wave in the first-order thickness-shear mode propagating through the piezoelectric layer of an example embodiment of the present invention. FIG. 4 is a schematic cross-sectional view for explaining the amplitude direction of a bulk wave in the first-order thickness-shear mode propagating through the piezoelectric layer of an example embodiment.

FIG. 3A illustrates such an acoustic wave device as described in Japanese Unexamined Patent Application Publication No. 2012-257019, in which a Lamb wave propagates through a piezoelectric film. Here, the wave propagates in a piezoelectric film 201 as indicated by arrows. In the piezoelectric film 201, a first main surface 201a and a second main surface 201b face each other, and the thickness direction connecting the first main surface 201a and the second main surface 201b is a Z direction. An X direction is a direction in which electrode fingers of the IDT electrode are arranged. As illustrated in FIG. 3A, in the Lamb wave, the wave propagates in the X direction as illustrated therein. Although the piezoelectric film 201 vibrates as a whole because of the plate wave, the wave propagates in the X direction, and thus reflectors are arranged on both sides to obtain resonance characteristics. Therefore, the propagation loss of waves occurs, and when miniaturization is achieved, that is, when the number of pairs of electrode fingers is reduced, the Q value is reduced.

In contrast, as illustrated in FIG. 3B, in the acoustic wave device of the present example embodiment, since the vibration displacement is in a thickness-shear direction, the wave propagates substantially in the direction connecting the other main surface 2a and the one main surface 2b of the piezoelectric layer 2, that is, in the Z direction, and the wave resonates. That is, the X-direction component of the wave is significantly smaller than the Z-direction component. Since the resonance characteristic is obtained by the propagation of the wave in the Z direction, no reflector is required. Therefore, no propagation loss occurs when the wave propagates to the reflector. Therefore, even when the number of electrode pairs each including the electrode 3 and the electrode 4 is reduced to achieve miniaturization, the Q value is less likely to be reduced.

As illustrated in FIG. 4, the amplitude direction of the bulk wave in the first-order thickness-shear mode is reversed between a first region 451 included in the excitation region C of the piezoelectric layer 2 and a second region 452 included in the excitation region C. FIG. 4 schematically illustrates a bulk wave in the case where a voltage is applied between the electrode 3 and the electrode 4 so that the electrode 4 has a higher potential than the electrode 3. The first region 451 is a region of the excitation region C between the other main surface 2a and a virtual plane VP1 that is orthogonal or substantially orthogonal to the thickness direction of the piezoelectric layer 2 and divides the piezoelectric layer 2 into two portions. The second region 452 is a region between the virtual plane VP1 and the one main surface 2b in the excitation region C.

As described above, in the acoustic wave device 1, at least one pair of electrodes including the electrode 3 and the electrode 4 is arranged, but since the acoustic wave device 1 does not propagate a wave in the X direction, the number of pairs of electrodes including the electrodes 3 and 4 is not necessary plural. That is, it is sufficient that at least one pair of electrodes is provided.

For example, the electrode 3 is an electrode connected to a hot potential, and the electrode 4 is an electrode connected to a ground potential. However, the electrode 3 may be connected to the ground potential, and the electrode 4 may be connected to the hot potential. In the present example embodiment, as described above, at least one pair of electrodes includes an electrode connected to the hot potential or an electrode connected to the ground potential, and no floating electrode is provided.

FIG. 5 is an explanatory diagram illustrating an example of resonance characteristics of the acoustic wave device of the present example embodiment. The design parameters of the acoustic wave device 1 having the resonance characteristics illustrated in FIG. 5 are as follows.

```
  Piezoelectric layer 2: LiNbO₃ having Euler angles (0°,
0°, 90°)
  Thickness of piezoelectric layer 2: about 400 nm
  Length of excitation region C: about 40 μm
  Number of pairs of electrodes 3 and 4: 21 pairs
  Inter-electrode center distance between electrode 3 and
electrode 4: about 3 μm
  Widths of electrode 3 and electrode 4: about 500 nm
  d/p = about 0.133
  Insulating layer 7: silicon oxide film having thickness
of about 1 μm.
```

### Support 8: Si

The length of the excitation region C is a dimension of the excitation region C along the length direction of the electrode 3 and the electrode 4. In the present example embodiment, the inter-electrode distances of the electrode pairs each including the electrode 3 and the electrode 4 were made all equal or substantially equal in the plurality of pairs. That is, the electrodes 3 and the electrodes 4 were arranged at an equal or substantially equal pitch.

As is clear from FIG. 5, although the reflector is not provided, a favorable resonance characteristic with a fractional bandwidth of about 12.5% is obtained.

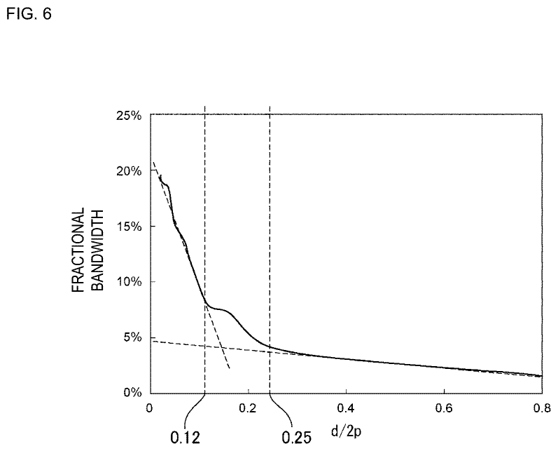

As described above, in the present example embodiment, d/p is, for example, equal to or less than about 0.5, and more preferably equal to or less than about 0.24, when d is the thickness of the piezoelectric layer 2 and p is the center-to-center distance between the electrode 3 and the electrode 4. This will be described with reference to FIG. 6.

A plurality of acoustic wave devices were obtained in the same or substantially the same manner as the acoustic wave device having the resonance characteristics illustrated in FIG. 5, except that d/2p was changed. FIG. 6 is an explanatory diagram illustrating the relationship between d/2p and the fractional bandwidth of the resonator in the acoustic wave device of the present example embodiment, when p is the center-to-center distance between adjacent electrodes or the average distance of the center-to-center distance, and d is the average thickness of the piezoelectric layer.

As is clear from FIG. 6, when d/2p exceeds about 0.25, that is, when d/p> about 0.5 is satisfied, the fractional bandwidth is less than about 5% even when d/p is adjusted. In contrast, when d/2p about 0.25, that is, d/p≤ about 0.5 is satisfied, the fractional bandwidth can be increased to equal to or more than about 5% by changing d/p within the range, that is, resonators having a high coupling coefficient can be provided. In addition, when d/2p is equal to or less than about 0.12, that is, when d/p is equal to or less than about 0.24, the fractional bandwidth can be increased to equal to or more than about 7%. In addition, by adjusting d/p within this range, a resonator having a wider fractional bandwidth can be obtained, and a resonator having a higher coupling coefficient can be provided. Therefore, it is understood that a resonator having a high coupling coefficient utilizing the bulk wave in the first-order thickness-shear mode can be configured by setting d/p to be, for example, equal to or less than about 0.5.

As described above, at least one pair of electrodes may be one pair, and the above p is defined as the center-to-center distance between the adjacent electrodes 3 and 4 in the case of one pair of electrodes. Additionally, in the case of equal to or more than 1.5 pairs of electrodes, the average distance of the center-to-center distances between the adjacent electrodes 3 and 4 may be p. In addition, when the piezoelectric layer 2 has a variation in thickness, the thickness d of the piezoelectric layer may be obtained from the average value of the thicknesses.

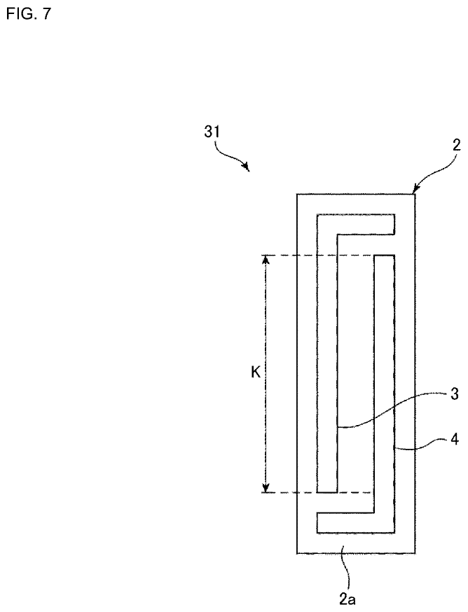

FIG. 7 is a plan view illustrating an example in which a pair of electrodes are provided in the acoustic wave device of the present example embodiment. In an acoustic wave device 31, a pair of electrodes including the electrode 3 and the electrode 4 are provided on the other main surface 2a of the piezoelectric layer 2. In FIG. 7, K is the intersecting width. As described above, in the acoustic wave device of the present invention, the number of pairs of electrodes may be one. Also in this case, when the above d/p is equal to or less than about 0.5, the bulk wave in the first-order thickness-shear mode can be effectively excited.

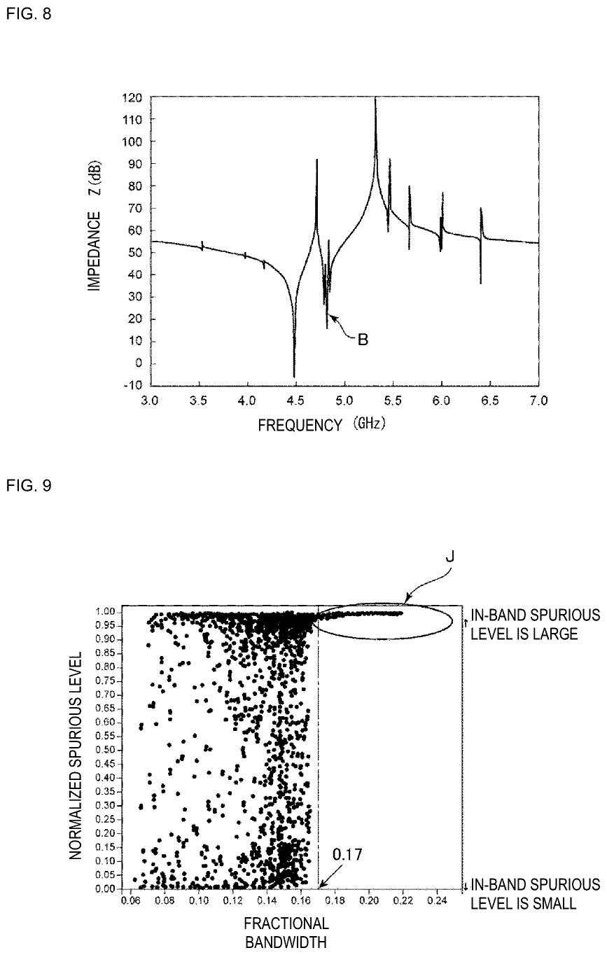

In the acoustic wave device 1, preferably, the metallization ratio MR of the adjacent electrodes 3 and 4 with respect to the excitation region, which is a region where any adjacent electrodes 3 and 4 among the plurality of electrodes 3 and 4 overlap each other when viewed in a direction in which the adjacent electrodes 3 and 4 face each other, satisfy MR about 1.75 (d/p)+0.075, for example. In this case, spurious emission can be effectively reduced. This will be described with reference to FIG. 8 and FIG. 9.

FIG. 8 is a reference diagram illustrating an example of resonance characteristics of the acoustic wave device of the present example embodiment. Spurious emission indicated by an arrow B appears between the resonant frequency and the anti-resonant frequency. FIG. 9 is a diagram illustrating a relationship between the fractional bandwidth and a phase rotation amount of spurious impedance normalized by about 180 degrees as the magnitude of the spurious emission when a large number of acoustic wave resonators are provided according to an example embodiment. Note that d/p= about 0.08 and the Euler angles of LiNbO₃ were (0°, 0°, 90°). In addition, the metallization ratio MR was set to about 0.35.

The metallization ratio MR will be explained with reference to FIG. 1B. In the electrode structure illustrated in FIG. 1B, when attention is paid to the pair of electrodes 3 and 4, it is assumed that only the pair of electrodes 3 and 4 are provided. In this case, the portion surrounded by a dashed-dotted line C is the excitation region. The excitation region includes a region in the electrode 3 overlapping the electrode 4, a region in the electrode 4 overlapping the electrode 3, and a region between the electrode 3 and the electrode 4 where the electrode 3 and the electrode 4 overlap each other, when the electrode 3 and the electrode 4 are viewed in a direction orthogonal to the length direction of the electrode 3 and the electrode 4, that is, in the facing direction.

The area of the electrodes 3 and 4 in the excitation region C with respect to the area of the excitation region is the metallization ratio MR. That is, the metallization ratio MR is the ratio of the area of the metallization portion with respect to the area of the excitation region. When a plurality of pairs of electrodes are provided, the ratio of the metallization portions included in the entire excitation region with respect to the total area of the excitation regions may be defined as MR.

FIG. 9 is a diagram illustrating a relationship between the fractional bandwidth and the phase rotation amount of the spurious impedance normalized by about 180 degrees as the magnitude of the spurious emission when a large number of acoustic wave resonators are provided according to the present example embodiment. The fractional bandwidth was adjusted by changing variously the film thickness of the piezoelectric layer and the dimensions of the electrodes. In addition, although FIG. 8 illustrates the results obtained when the piezoelectric layer formed of Z-cut LiNbO₃ is used, the same tendency is obtained when a piezoelectric layer having another cut angle is used.

In the region surrounded by an ellipse J in FIG. 9, the spurious emission is as large as about 1.0. As is clear from FIG. 9, when the fractional bandwidth exceeds about 0.17, that is, when the fractional bandwidth exceeds about 17%, a large spurious emission having a spurious level of about 1 or more appears in a pass band even when the parameters defining the fractional bandwidth are changed. That is, as in the resonance characteristics illustrated in FIG. 8, a large spurious emission indicated by the arrow B appears in the band. Therefore, the fractional bandwidth is, for example, preferably equal to or less than about 17%. In this case, the spurious emission can be reduced by adjusting the film thickness of the piezoelectric layer 2 and the dimensions of the electrode 3 and the electrode 4.

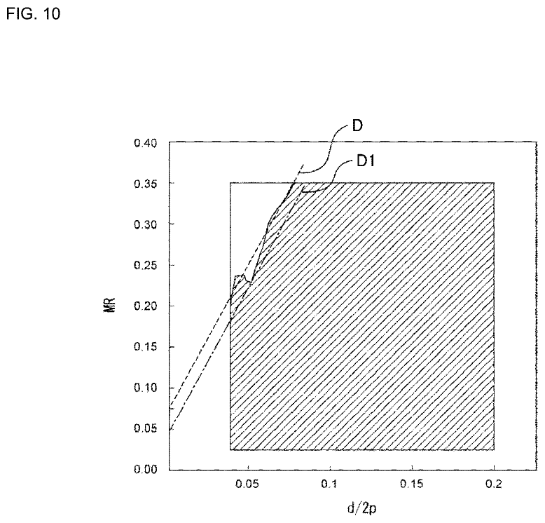

FIG. 10 is a diagram illustrating a relationship between d/2p, the metallization ratio MR, and the fractional bandwidth. In the above acoustic wave device, various acoustic wave devices having different d/2p and MR were formed, and the fractional bandwidth was measured. The hatched portion on the right side of a broken line D in FIG. 10 is a region where the fractional bandwidth is equal to or less than about 17%. The boundary between the hatched region and the unhatched region is represented by MR= about 3.5 (d/2p)+0.075. That is, MR= about 1.75 (d/p)+0.075. Therefore, for example, preferably, MR≤ about 1.75 (d/p)+0.075 is satisfied. In this case, the fractional bandwidth is easily set to equal to or less than about 17%. More preferably, for example, it is a region on the right side of MR= about 3.5 (d/2p)+0.05 indicated by a dashed-dotted line Dl in FIG. 10. That is, when MR≤ about 1.75 (d/p)+0.05 is satisfied, the fractional bandwidth can be reliably set to equal to or less than about 17%.

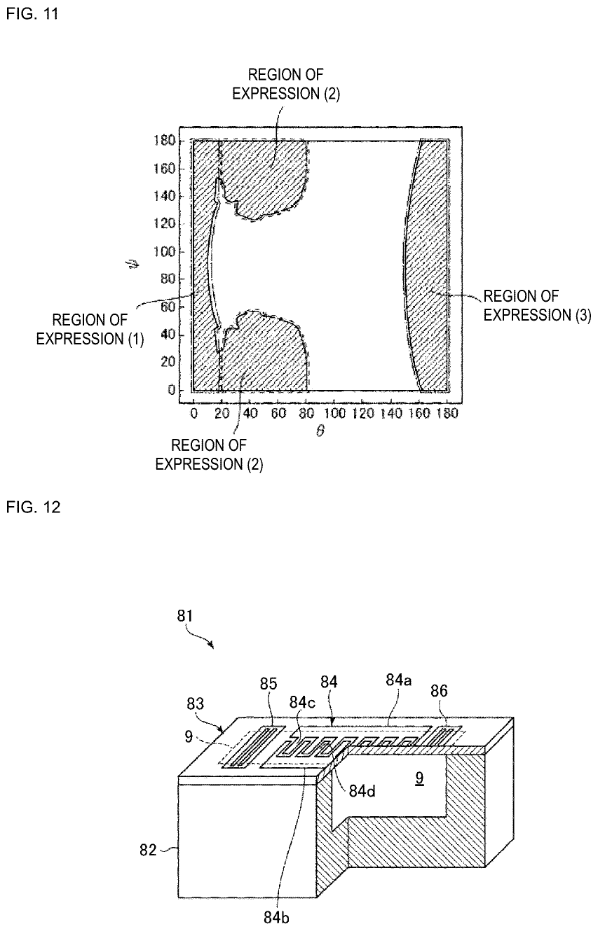

FIG. 11 is a diagram illustrating a map of the fractional bandwidth with respect to the Euler angles (0°, 0, $) of LiNbO₃ when d/p approaches 0 as much as possible. The hatched portion in FIG. 11 is a region where a fractional bandwidth of at least equal to or more than about 5% is obtained. The range of this region is approximated to the range represented by the following Expression (1), Expression (2), and Expression (3).

$$( 0 ° \pm 10 ° , 0 ° to 20 ° , arbitrary ψ ) \qquad Expression ( 1 )$$

$$( 0 ° \pm 10 ° , 20 ° to 80 ° , 0 ° to 60 ° {( 1 - {( θ - 50 )}^{2} / 900 )}^{1 / 2} ) or \qquad Expression ( 2 )$$

$$( 0 ° \pm 10 ° , 20 ° to 80 ° , [ 180 ° - 60 {° ( 1 - {( θ - 50 )}^{2} / 900 )}^{1 / 2} ] to 180 ° )$$

$$( 0 ° \pm 10 ° , [ 180 ° - 30 {° ( 1 - {( ψ - 90 )}^{2} / 8100 )}^{1 / 2} ] to 180 ° , arbitrary ψ ) \qquad Expression ( 3 )$$

Therefore, the fractional bandwidth can be sufficiently increased when the Euler angles satisfy the above Expression (1), Expression (2), or Expression (3), which is preferable. The basic configuration of the acoustic wave device has been described above, but the present invention may be applied to an acoustic wave device 81 according to the following modification.

FIG. 12 is a partially cutaway perspective view of an acoustic wave device of a modification of an example embodiment of the present invention. As illustrated in FIG. 12, the acoustic wave device 81 of the present modification includes a support substrate 82. The support 8 (see FIG. 1A, etc.) is cut into a plate shape. The support substrate 82 of the support 8 is provided with a recess that is open on the upper surface. A piezoelectric layer 83 is laminated on the support substrate 82. Thus, the cavity portion 9 is provided. An IDT electrode 84 is provided on the piezoelectric layer 83 above the cavity portion 9. A reflector 85 and a reflector 86 are provided on both sides of the IDT electrode 84 in the acoustic wave propagation direction.

In FIG. 12, the outer peripheral edge of the cavity portion 9 is indicated by a broken line. In this case, the IDT electrode 84 includes a first busbar 84a, a second busbar 84b, a plurality of electrodes 84c as first electrode fingers, and a plurality of electrodes 84d as second electrode fingers. The plurality of electrodes 84c is connected to the first busbar 84a. The plurality of electrodes 84d is connected to the second busbar 84b. The plurality of electrodes 84c and the plurality of electrodes 84d are interdigitated.

In the acoustic wave device 81, an alternating electric field is applied to the IDT electrode 84 on the cavity portion 9, and thus a Lamb wave as a plate wave is excited. Since the reflector 85 and the reflector 86 are provided on both sides, the resonance characteristics by the Lamb wave can be obtained. As described above, an acoustic wave device according to an example embodiment of the present invention may use a plate wave. Next, the acoustic wave device of the present example embodiment will be described in detail.

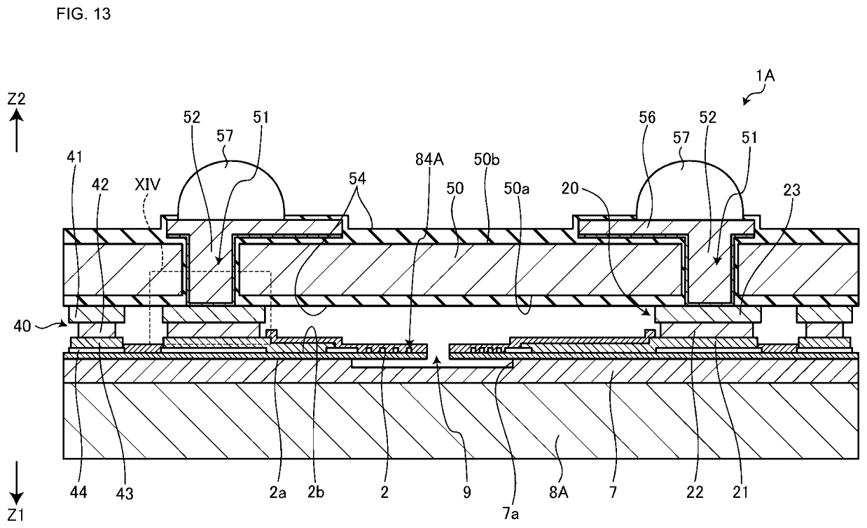

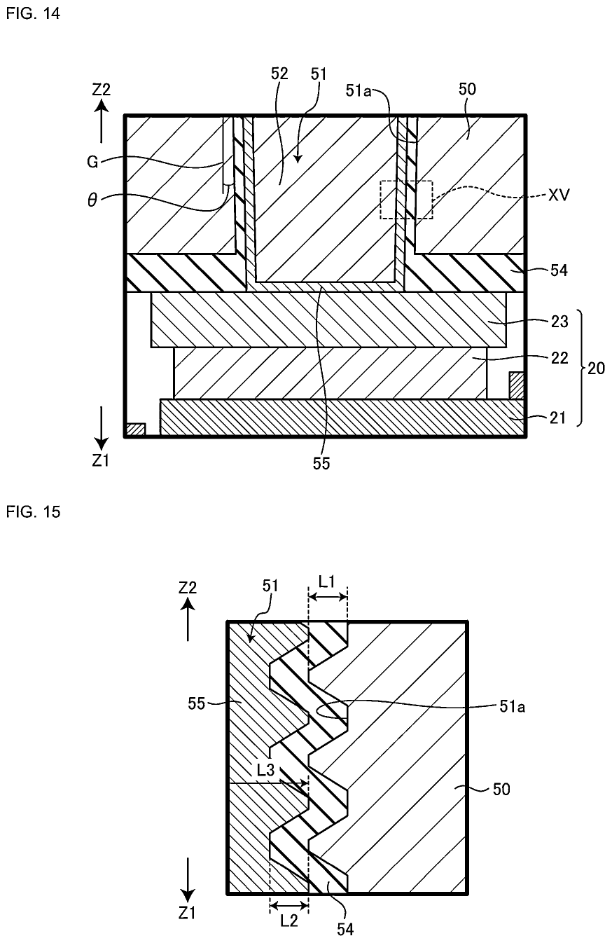

FIG. 13 is a schematic view illustrating the configuration of an acoustic wave device according to an example embodiment. FIG. 14 is an enlarged view of a range surrounded by a frame line XIV in FIG. 13.

As illustrated in FIG. 13, an acoustic wave device 1A includes a first substrate 8A, the piezoelectric layer 2, a functional electrode 84A, and a second substrate 50. In addition, the first substrate 8A, the piezoelectric layer 2, the functional electrode 84A, and the second substrate 50 are arranged in this order in the thickness direction of the first substrate 8A. In addition, a through-hole 51 is provided in the second substrate 50. A via electrode 52 is provided in the through-hole 51.

The first substrate 8A is obtained by cutting the support 8 (see FIG. 1A, etc.) into a plate shape. The piezoelectric layer 2 includes the one main surface 2a facing the first substrate 8A in the thickness direction of the first substrate 8A, and the other main surface 2b facing the direction opposite to the one main surface 2b in the thickness direction. The insulating layer 7 (see FIG. 1A, etc.) is provided between the first substrate 8A and the piezoelectric layer 2. The insulating layer 7 may be referred to as an intermediate layer. Hereinafter, a direction in which the one main surface 2a faces in the thickness direction of the first substrate 8A is referred to as a first thickness direction Z1. In addition, the direction opposite to the first thickness direction Z1 is referred to as a second thickness direction Z2.

In the present example embodiment, the opening portion 7a is provided in a center portion of the insulating layer 7. On the other hand, the opening portion 8a (see FIGS. 1A and 1B) is not provided in the first substrate 8A. Thus, the first thickness direction Z1 of the cavity portion 9 is covered with the first substrate 8A.

The functional electrode 84A is the IDT electrode 84 (see FIG. 12) and is provided on the other main surface 2b of the piezoelectric layer 2. In an example embodiment of the present invention, the functional electrode 84A may be provided on at least one of the one main surface 2b and the other main surface 2a of the piezoelectric layer 2. In addition, a wiring layer 20 that electrically connects the functional electrode 84A and the via electrode 52 is provided between the piezoelectric layer 2 and the second substrate 50. The wiring layer 20 includes an intermediate wiring layer 21, a second wiring layer 22, and a first wiring layer 23 that are laminated in this order from the first thickness direction Z1. The intermediate wiring layer 21 is electrically connected to the first busbar 84a and the second busbar 84b (see FIG. 12) of the functional electrode 84A.

The second wiring layer 22 is, for example, an Au layer. The first wiring layer 23 includes a plurality of layers made of different metals, and in the present example embodiment, the first wiring layer 23 includes, for example, a Ti layer, a Pt layer, and an Au layer that are laminated in this order from the via electrode side (the second thickness direction Z2). In addition, the second wiring layer 22 is provided on the first substrate 8A side, and the first wiring layer 23 is provided on the second substrate 50 side. When the first substrate 8A and the second substrate 50 are bonded to each other, the Au layer of the second wiring layer 22 and the Au layer of the first wiring layer 23 are bonded to each other (Au—Au bonding).

In addition, a frame portion 40 surrounding the functional electrode 84A and the wiring layer 20 is provided between the piezoelectric layer 2 and the second substrate 50. The frame portion 40 seals portions between the piezoelectric layer 2 and the second substrate 50. The frame portion 40 includes a first frame layer 41, a second frame layer 42, a third frame layer 43, and a fourth frame layer 44 that are laminated in this order from the second thickness direction Z2. The first frame layer 41 is made of the same material as the first wiring layer 23. That is, the first frame layer 41 is formed on the second substrate 50 simultaneously with the first wiring layer 23. Similarly, the second frame layer 42 is made of the same material as the second wiring layer 22, and is formed on the first substrate 8A simultaneously with the second wiring layer 22. Thus, the first frame layer 41 and the second frame layer 42 are bonded to each other by Au—Au bonding, as in the case of the first wiring layer 23 and the second wiring layer 22. A third frame layer 43 is made of the same material as the intermediate wiring layer 21, and is a layer formed simultaneously with the intermediate wiring layer 21. A fourth frame layer 44 is made of the same material as the functional electrode 84A, and is a layer formed simultaneously with the functional electrode 84A.

In the present example embodiment, the second substrate 50 is made of, for example, Si. However, the material of the second substrate 50 is not limited to Si, and the same kind of material as the first substrate 8A can be used. The second substrate 50 includes a first main surface 50a facing the first thickness direction Z1, a second main surface 50b facing the second thickness direction Z2, and the through-hole 51 penetrating from the first main surface 50a to the second main surface. The first main surface 50a faces the other main surface 2b of the piezoelectric layer 2. The second main surface 50b faces the direction opposite to the first main surface 50a in the thickness direction.

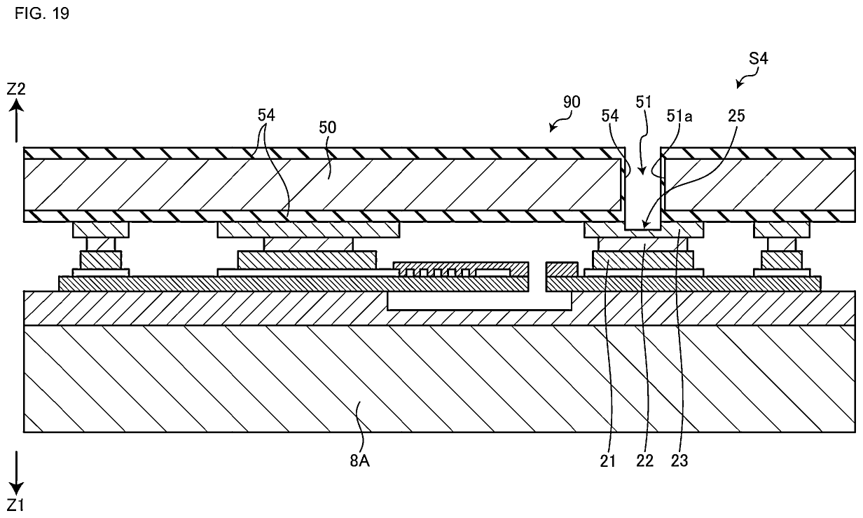

The through-hole 51 penetrates the second substrate 50 in the thickness direction. The first wiring layer 23 is arranged on the bottom portion of the through-hole 51 in the first thickness direction Z1. The first wiring layer 23 (wiring layer 20) is provided with a recess 25 recessed from the through-hole 51 toward the first thickness direction Z1 (see FIG. 19).

As illustrated in FIG. 14, an angle θ between a side surface 51a of the through-hole 51 and a normal line G to the second main surface 50b is, for example, equal to or more than about 0° and equal to or less than about 5°. The normal line G is referred to as a virtual line extending in the first thickness direction from an intersecting portion (corner portion) between the side surface 51a and the second main surface 50b. Therefore, the side surface 51a of the through-hole 51 of the present example embodiment has a small inclination angle, and the opening of the through-hole 51 in the second main surface 50b is also small.

As illustrated in FIG. 13, an insulating layer 54 is provided on the first main surface 50a and the second main surface 50b. The insulating layer 54 is, for example, a silicon oxide film made of Si. In addition, as illustrated in FIG. 14, the insulating layer 54 is also provided on the side surface 51a of the through-hole 51. That is, the insulating layer (silicon oxide film) 54 covers the side surface 51a of the through-hole 51. A seed layer 55 is provided on the inner peripheral side of the insulating layer 54 provided on the side surface 51a of the through-hole 51. The seed layer 55 is connected to the first wiring layer 23 arranged at the bottom portion of the through-hole 51 in the first thickness direction Z1. The seed layer 55 is, for example, preferably a single layer of Cu or Ti from the viewpoint of adhesion to the second substrate 50 and low resistance. Alternatively, the seed layer 55 is, for example, preferably formed by laminating a Ti layer and a Cu layer in this order.

The via electrode 52 is provided in the through-hole 51 and on the inner peripheral side of the seed layer 55. That is, the seed layer 55 is arranged between the via electrode 52 and the insulating layer (silicon oxide film) 54. In addition, the end portion of the via electrode 52 in the first thickness direction Z1 is electrically connected to the first wiring layer 23 via the seed layer 55. In addition, as illustrated in FIG. 13, an under bump metal 56 is provided at the via electrode 52 in the second thickness direction Z2. A bump 57 is laminated on the under bump metal 56 in the second thickness direction Z2.

As described above, according to the present example embodiment, since the opening of the through-hole 51 in the second thickness direction Z2 is small, the region occupied by the via electrode 52 on the second main surface 50b of the second substrate 50 is also small. Therefore, the layout of the second main surface 50b of the second substrate 50 is improved. Next, the inside of the through-hole 51 will be described in detail.

FIG. 15 is an enlarged view of a portion surrounded by a frame line XV in FIG. 14. The side surface 51a of the through-hole 51 is provided with unevenness formed in the process of forming the through-hole 51. A surface roughness L1 of the side surface 51a is, for example, equal to or more than about 10 nm. The surface roughness of the side surface 51a is the height of a convex portion protruding toward the through-hole 51 with reference to a recess formed as the bottom of the unevenness. That is, a height L1 of the convex portion of the side surface 51a having the unevenness is, for example, equal to or more than about 10 nm. Hereinafter, the height of the convex portion of the side surface 51a having the unevenness is simply referred to as the height of the side surface 51a. According to this amount of height, an anchor effect is obtained, and the insulating layer 54 and the seed layer 55 provided on the inner peripheral side of the side surface 51a are less likely to peel off. On the other hand, when the amount of height of the convex portion is increased, the insulating layer 54 and the seed layer 55 provided on the inner peripheral side of the side surface 51a may be disconnected. Here, in the case where the insulating layer 54 is, for example, a silicon oxide film, the film thickness of equal to or more than about 100 nm ensures the insulating properties to make the functional film. Therefore, when the insulating layer 54 is the silicon oxide film, the height L1 (surface roughness) of the convex portion of the side surface 51a of the through-hole 51 is, for example, equal to or less than about 100 nm in order to prevent disconnection of the insulating layer 54 having the film thickness of equal to or more than at least 100 nm. In an example embodiment of the present invention, the height (surface roughness) L1 of the convex portion of the side surface 51a may be, for example, less than about 10 nm or may exceed about 100 nm. The amount of height of the convex portion can be confirmed by a scanning electron microscope (SEM).

In addition, a thickness L2 of the insulating layer 54 is, for example, equal to or more than about 50 nm and equal to or less than about 3 μm. Preferably, the thickness L2 of the insulating layer 54 is, for example, greater than about 100 nm and equal to or less than about 1 μm. This is because the height (surface roughness) L1 of the convex portion of the side surface 51a is equal to or less than about 100 nm, and thus, when the thickness L2 of the insulating layer 54 is greater than about 100 nm, the disconnection does not occur. In an example embodiment of the present invention, the thicknesses L2 of the insulating layers 54 may, for example, exceed about 50 nm or be less than about 3 μm.

In addition, a thickness L3 of the seed layer 55 is larger than the height L1 (surface roughness) of the convex portion of the side surface 51a and is, for example, equal to or less than about 300 μm. When the seed layer is formed by laminating the Ti layer and the Cu layer in this order, the Ti layer and the Cu layer are laminated in this order on the insulating layer (silicon oxide film) 54. In addition, when the seed layer 55 is a single layer of, for example, the Ti layer, the Ti layer is laminated on the insulating layer (silicon oxide film) 54. The thickness of the Ti layer of the seed layer 55 is larger than the height L1 (surface roughness) of the convex portion of the side surface 51a and is, for example, equal to or less than about 300 μm. This avoids disconnection of the seed layer 55 (Ti layer). In an example embodiment of the present invention, the thickness L3 of the seed layer 55 (Ti layer) may be, for example, equal to or less than the height L1 (surface roughness) of the convex portion of the side surface 51a or may exceed about 300 μm. In an example embodiment of the present invention, when the seed layer 55 is formed of a single Cu layer, the thickness of the Cu layer may be larger than the height L1 (surface roughness) of the convex portion of the side surface and may be, for example, equal to or less than about 300 μm. This is because the disconnection of the Cu layer can be avoided also by this.

Next, an example of a method of manufacturing the acoustic wave device according to the present example embodiment will be described. The method of manufacturing the acoustic wave device includes a bonding step S1, a through-hole forming step S2, an insulating film forming step S3, a dry etching step S4, a seed layer laminating/resist film forming/plate processing step S5, a resist film removing/window forming step S6, a dicing step S7, a soldering step S8, and a singulation/polishing step S9.

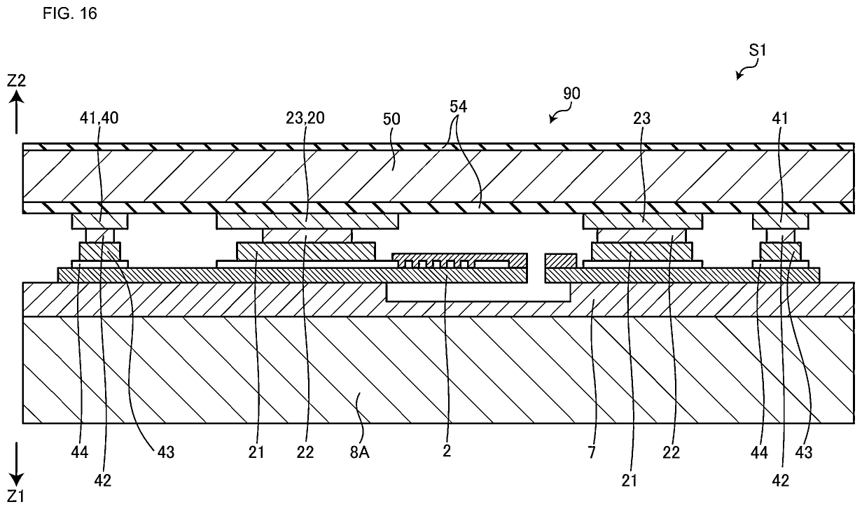

FIG. 16 is a cross-sectional view illustrating an intermediate product after the bonding step of the example embodiment. As illustrated in FIG. 16, the bonding step S1 is a step of bonding the first substrate 8A and the second substrate 50. Before the bonding step S1, the intermediate wiring layer 21 and the second wiring layer 22 of the wiring layer 20 are provided on the first substrate 8A side. The first wiring layer 23 is provided on the second substrate 50 side. In addition, the second frame layer 42, the third frame layer 43, and the fourth frame layer 44 of the frame portion 40 are provided on the first substrate 8A side. The first frame layer 41 is provided on the second substrate 50 side.

In the bonding step S1, the second wiring layer 22 (Au layer) and the Au layer of the first wiring layer 23 are bonded by Au—Au bonding. In addition, the second frame layer 42 (Au layer) and the Au layer of the first frame layer 41 are bonded by Au—Au bonding. Thus, as illustrated in FIG. 16, the second wiring layer 22 and the first wiring layer 23 are bonded to each other, and the second frame layer 42 and the Au layer of the first frame layer 41 are bonded to each other. Thus, an intermediate product 90 in which the first substrate 8A and the second substrate 50 are integrated is manufactured. When manufacturing the acoustic wave device, a large number of acoustic wave devices are manufactured at once. That is, the intermediate product 90 illustrated in FIG. 16 is a portion (one) of an aggregated intermediate product in which the plurality of intermediate products 90 is aggregated. In addition, the intermediate product 90 may be referred to as a processing object (object) of each step.

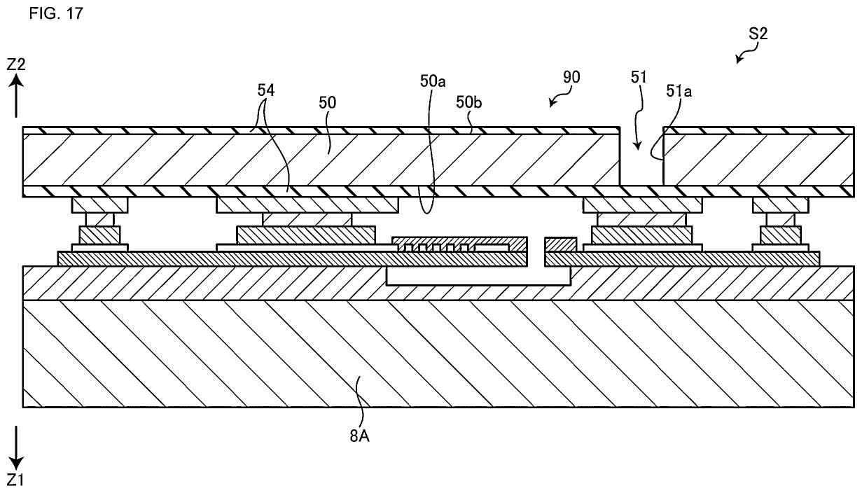

FIG. 17 is a cross-sectional view illustrating the intermediate product after the through-hole forming step of the example embodiment. As illustrated in FIG. 17, the through-hole forming step S2 is a step of forming the through-hole 51 in the second substrate 50 of the intermediate product 90. The method of forming the through-hole 51 repeatedly performs a step of performing isotropic etching the second main surface 50b of the second substrate 50, a step of depositing a protective film on the side surface and the bottom surface of the hole formed by the isotropic etching, and a step of etching the protective film on the bottom surface. According to this, the angle θ of the side surface 51a of the through-hole 51 is, for example, equal to or more than about 0° and equal to or less than about 5° with respect to the normal line G of the second main surface 50b (see FIG. 14).

Additionally, in the present example embodiment, the insulating layer 54 is provided on the second main surface 50b of the second substrate 50. Therefore, in the present example embodiment, a portion of the insulating layer 54 provided on the second main surface 50b is also removed by the through-hole forming step S2. In addition, unevenness is formed on the side surface 51a of the through-hole 51 (see FIG. 15) by the through-hole forming step S2. In addition, the height L1 of the convex portion of the side surface 51a is, for example, equal to or more than about 10 nm.

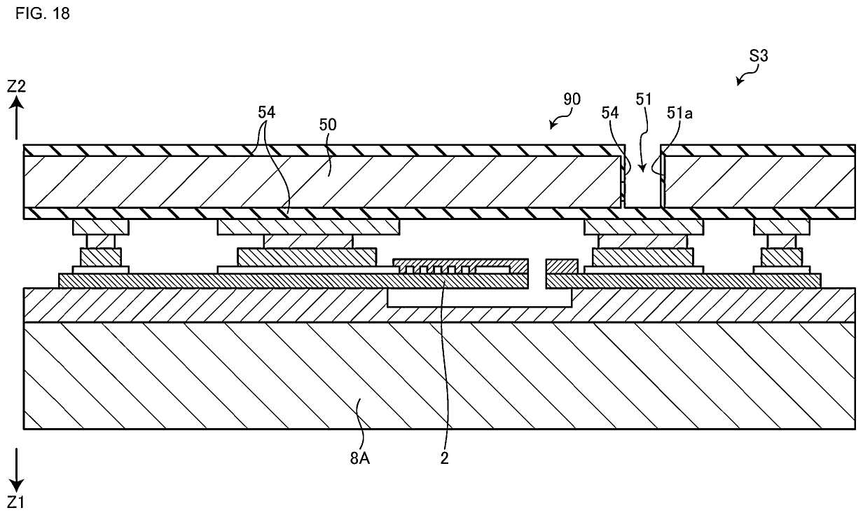

FIG. 18 is a cross-sectional view illustrating the intermediate product after the insulating film forming step of the example embodiment. The insulating film forming step S3 is a step of forming the insulating layer 54 on the side surface 51a of the through-hole 51. As a method of forming the insulating layer 54, for example, tetra ethoxy silane (TEOS) is used.

FIG. 19 is a cross-sectional view illustrating the intermediate product after the dry etching step of the example embodiment. The dry etching step S4 is a step of removing the insulating layer 54 exposed from the through-hole 51. The insulating layer 54 exposed from the through-hole 51 is the insulating layer 54 laminated on the wiring layer 20. Thus, in the dry etching step S4, a part of the wiring layer 20 is exposed from the through-hole 51.

A gas used in the dry etching step S4 is, for example, any one of C4F8 gas, CF4 gas, CHF3 gas, and SF6 gas. In addition, the dry etching step S4 is performed to meet an over-edge condition. Thus, the recess 25 is formed in the wiring layer 20 arranged at the insulating layer 54 in the first thickness direction Z1. The recess 25 is formed in the first wiring layer 23 of the wiring layer 20 arranged in the second thickness direction Z2.

Here, the first wiring layer 23 is formed by laminating the Ti layer, the Pt layer, and the Au layer in this order from the second thickness direction Z2. Therefore, when the amount of depth of the recess 25 is to the extent that a portion of the Ti layer in the thickness direction is removed, the bottom surface of the recess 25 is the Ti layer. In addition, when the amount of depth of the recess 25 is to the extent that the Ti layer is removed entirely in the thickness direction, the bottom surface of the recess 25 is the Pt layer. In addition, when the depth size of the recess 25 is to the extent that the Ti layer and the Pt layer are removed, the bottom surface of the recess 25 is the Au layer. As described above, in the present example embodiment, the bottom surface of the recess 25 may be any of the Ti layer, the Pt layer, and the Au layer.

In an example embodiment of the present invention, the first wiring layer 23 may be formed of a material other than the Ti layer, the Pt layer, and the Au layer. In such a case (the case where the first wiring layer 23 includes the first layer, . . . , the (n−1)-th layer, and the n-th layer laminated in order from the second thickness direction Z2), the bottom surface of the recess may be the (n−1)-th layer. Note that n is an integer of 2 or more.

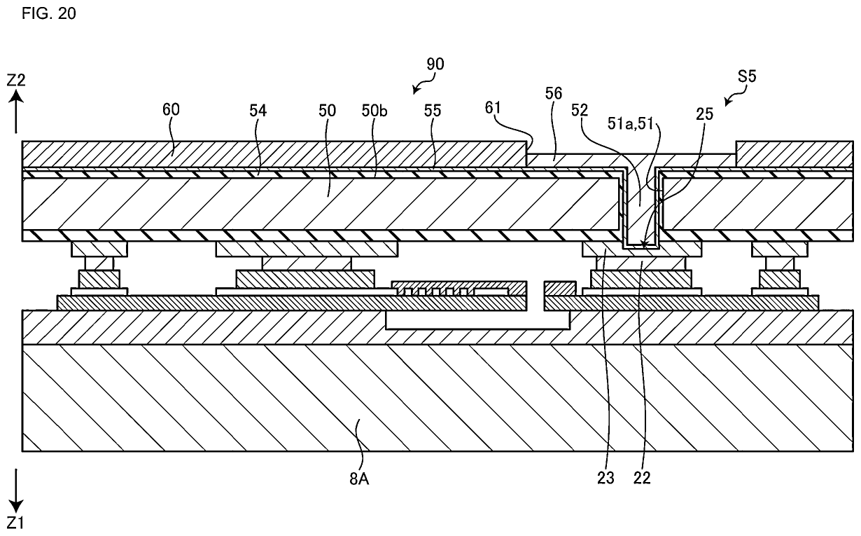

FIG. 20 is a cross-sectional view illustrating the intermediate product after the seed layer laminating/resist film forming/plate processing step of the present example embodiment. The seed layer laminating/resist film forming/plate processing step S5 is a step of forming the seed layer 55, then forming the resist film, and then performing the plate processing.

To be specific, portions where the seed layer 55 is laminated are the insulating layer 54 provided on the second main surface 50b of the second substrate 50, the side surface 51a of the through-hole 51, and the recess 25. Here, the seed layer 55 laminated in the recess 25 is laminated on any one of the Ti layer, the Pt layer, and the Au layer in the first wiring layer 23. In addition, in the case where the seed layer 55 is formed of lamination of the Ti layer and the Cu layer, when the layer in contact with the seed layer 55 is a single layer of the Ti layer or the Pt layer, the Ti layer and the Cu layer are laminated in this order on the first wiring layer 23. The step of laminating the seed layer 55 in the seed layer laminating/resist film forming/plate processing step S5 may be referred to as a seed layer laminating step.

A resist film 60 is laminated on the seed layer 55 laminated on the second main surface 50b in the second thickness direction Z2. In addition, the resist film 60 is provided with an opening portion 61. The opening portion 61 exposes the through-hole 51 and the periphery of the opening of the through-hole 51 in the second thickness direction Z2.

The plate processing is performed on the portion exposed from the opening portion 61 of the resist film 60. Further, before the plate processing, it is preferable to perform surface treatment on the portion exposed from the opening portion 61 of the resist film 60 by, for example, a PR method. The plate processing is performed in the order of Au, Ti, and Cu. As a result, the via electrode 52 is formed in the through-hole 51. In addition, the under bump metal 56 is formed in the opening portion 61.

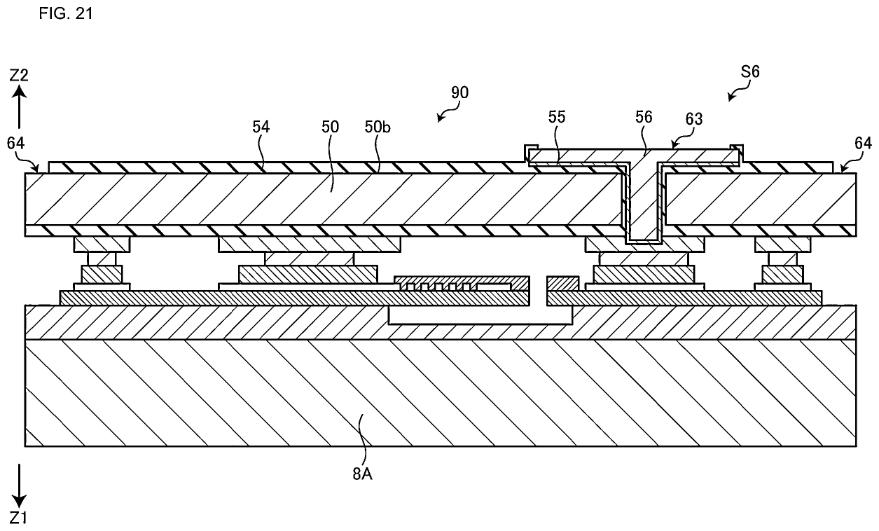

FIG. 21 is a cross-sectional view illustrating the intermediate product after the resist film removing/window forming step of the present example embodiment. As illustrated in FIG. 21, the resist film removing/window forming step S6 is a step of removing the resist film 60 and then forming a bump window 63 and a dicing window 64. When the resist film 60 is removed, an excess seed layer 55 is also removed. Note that the excess seed layer 55 is the seed layer 55 laminated on the insulating layer 54 on the second main surface 50b.

The forming the bump window 63 and the dicing window 64 includes providing a resist layer (not illustrated) at portions where the bump window 63 and the dicing window 64 are to be formed, and forming an insulating film on the resist layer. Thereafter, the resist layer is removed. According to this, the portion where the resist layer is provided becomes an opening portion which is not covered with the insulating layer. In addition, the central portion of the under bump metal 56 in the second thickness direction Z2 is exposed by the bump window 63. Further, the boundary, on the second main surface 50b of the second substrate 50, between the plurality of intermediate products 90 is exposed by the dicing window 64.

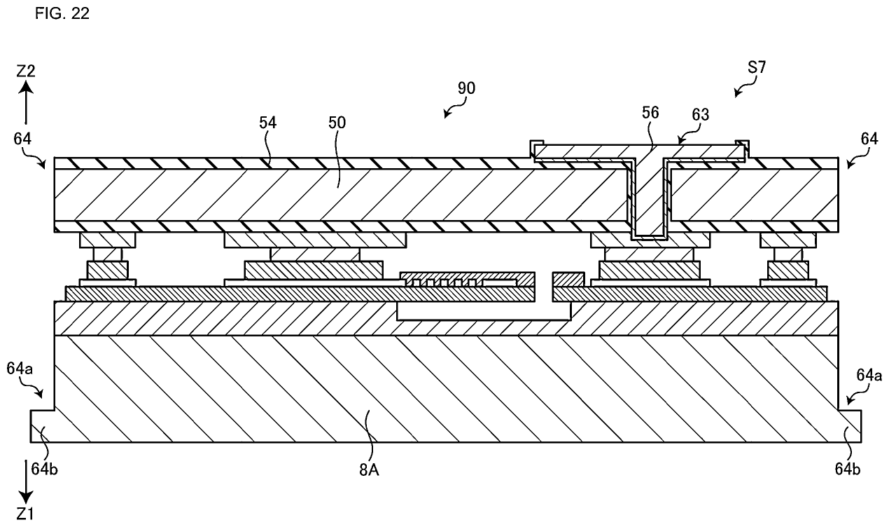

FIG. 22 is a cross-sectional view illustrating the intermediate product after the dicing step of the example embodiment. The dicing step S7 is a step of performing cutting in the thickness direction by dicing. Specifically, the second substrate 50 is cut by cutting a portion of the second substrate 50 exposed from the dicing window 64. After the second substrate 50 is cut, the first substrate 8A is also cut in a range overlapping the dicing window 64, and a cut 64a is formed in the first substrate 8A. According to this, the plurality of intermediate products 90 is connected to each other via a coupling portion 64b (a part of the first substrate 8A).

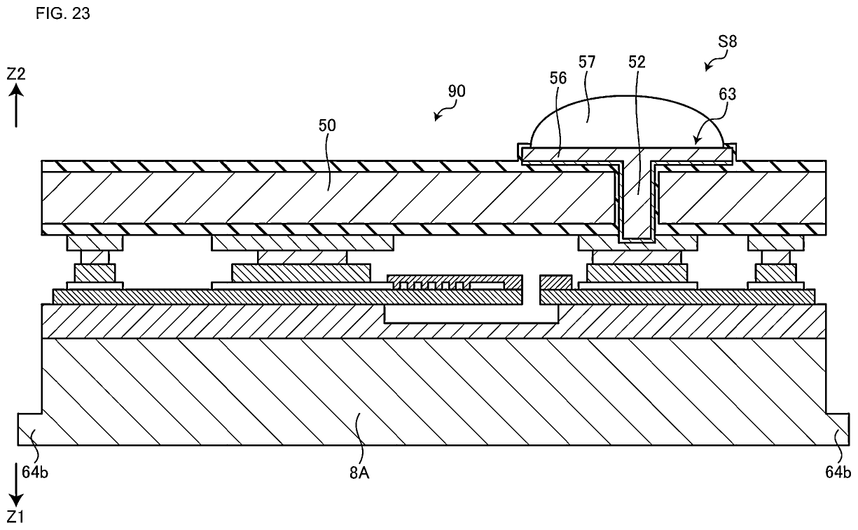

FIG. 23 is a cross-sectional view of the intermediate product after soldering of the present example embodiment. The soldering step S8 is a step of solder printing on a portion of the under bump metal 56 exposed from the bump window 63 and then flowing the solder to form the bump 57.

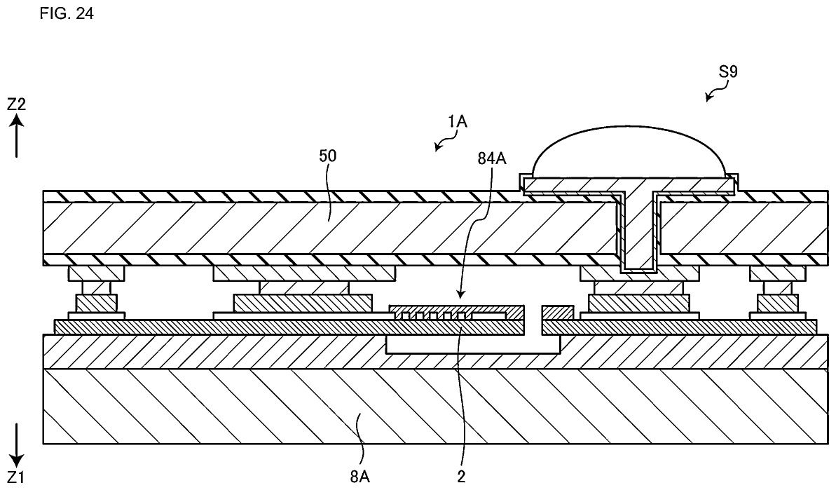

FIG. 24 is a cross-sectional view of the acoustic wave device after the singulation/polishing step of the example embodiment. The singulation/polishing step S9 is a step of dividing the intermediate product 90 into individual pieces by cutting the coupling portion 64b and then polishing the first substrate 8A. The first substrate 8A is polished from the surface of the first substrate 8A in the first thickness direction Z1 to such an extent that the coupling portion 64b does not remain. Thus, the plurality of acoustic wave devices 1 is manufactured, and the method of manufacturing the acoustic wave device 1A is completed.

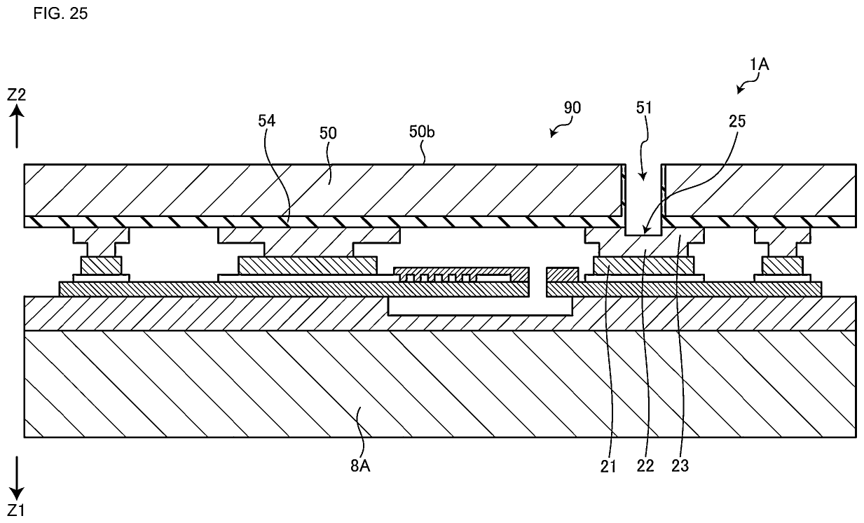

FIG. 25 is a schematic view illustrating the configuration of an acoustic wave device according to a modification of an example embodiment of the present invention. Although the example embodiments have been described above, the present invention is not limited to the examples shown in the example embodiments. For example, as illustrated in FIG. 25, in the acoustic wave device 1A, the first wiring layer 23 may be a single layer made of Au. In addition, the insulating layer 54 need not be laminated on the second main surface 50b of the second substrate 50.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a first substrate;
a piezoelectric layer including one main surface facing the first substrate in a thickness direction of the first substrate and another main surface facing a direction opposite to the one main surface in the thickness direction;
a functional electrode on at least one of the one main surface and the other main surface of the piezoelectric layer; and
a second substrate including a first main surface facing the other main surface of the piezoelectric layer, a second main surface facing a direction opposite to the first main surface in the thickness direction, and a through-hole penetrating from the first main surface to the second main surface; wherein
an angle at which a side surface of the through-hole is inclined from the second main surface toward the first main surface is equal to or more than about 0° and equal to or less than about 5° based on a normal line with respect to the second main surface.

2. The acoustic wave device according to claim 1, further comprising:
a via electrode in the through-hole; and
a wiring layer between the piezoelectric layer and the second substrate and electrically connecting the functional electrode and the via electrode; wherein
the wiring layer includes a recess in a portion facing the through-hole.

3. The acoustic wave device according to claim 2, wherein
the wiring layer includes a first wiring layer and a second wiring layer laminated in order from a via electrode side;
the first wiring layer includes a plurality of layers made of different metals;
the plurality of layers includes a first layer, . . . , an (n−1)-th layer, and an n-th layer that are laminated in order from the via electrode;
a bottom surface of the recess is an (n−1)-th layer, and the via electrode is connected to an (n−1)-th layer.

4. The acoustic wave device according to claim 3, wherein
the first wiring layer includes a Ti layer, a Pt layer, and an Au layer laminated in order from the via electrode side;
the bottom surface of the recess is the Pt layer; and
the via electrode is connected to the Pt layer.

5. The acoustic wave device according to claim 2, wherein
the wiring layer includes a first wiring layer and a second wiring layer laminated in order from the via electrode side;
the first wiring layer includes a Ti layer, a Pt layer, and an Au layer laminated in order from the via electrode side;
a bottom surface of the recess is the Ti layer; and
the via electrode is connected to the Ti layer.

6. The acoustic wave device according to claim 4, wherein the second wiring layer includes an Au layer bonded to the Au layer of the first wiring layer.

7. The acoustic wave device according to claim 3, wherein
a seed layer is provided between the via electrode and the first wiring layer; and
the seed layer is a single layer made of Cu or Ti.

8. The acoustic wave device according to claim 3, wherein
a seed layer is provided between the via electrode and the first wiring layer; and
the seed layer includes a Ti layer and a Cu layer laminated in order on the first wiring layer.

9. The acoustic wave device according to claim 1, wherein a surface roughness of the side surface is equal to or more than about 10 nm.

10. The acoustic wave device according to claim 9, wherein the surface roughness of the side surface is equal to or less than about 100 nm.

11. The acoustic wave device according to claim 10, further comprising a silicon oxide film covering the side surface.

12. The acoustic wave device according to claim 11, wherein a thickness of the silicon oxide film is equal to or more than about 50 nm and equal to or less than about 3 μm.

13. The acoustic wave device according to claim 12, wherein a thickness of the silicon oxide film is greater than about 100 nm and is equal to or less than about 1 μm.

14. The acoustic wave device according to claim 11, further comprising:
a via electrode located in the through-hole; wherein
a seed layer is provided between the via electrode and the silicon oxide film.

15. The acoustic wave device according to claim 14, wherein the seed layer is a single layer made of Cu or Ti.

16. The acoustic wave device according to claim 14, wherein the seed layer includes a Ti layer and a Cu layer laminated in order on the silicon oxide film.

17. The acoustic wave device according to claim 16, wherein a thickness of a Ti layer of the seed layer is larger than the surface roughness and is equal to or less than about 300 μm.

18. A method of manufacturing an acoustic wave device comprising:
forming a through-hole in an object, the object including a first substrate, a piezoelectric layer including one main surface facing the first substrate in a thickness direction of the first substrate and another main surface facing a direction opposite to the one main surface in the thickness direction, a functional electrode on at least one of the one main surface and the other main surface of the piezoelectric layer, a second substrate including a first main surface facing the other main surface of the piezoelectric layer and a second main surface facing a direction opposite to the first main surface in the thickness direction, and a wiring layer between the piezoelectric layer and the second substrate and bonding the piezoelectric layer and the second substrate; wherein
the through-hole is formed in the second main surface of the second substrate by repeatedly performing:
isotropic etching;
depositing a protective film on a side surface and a bottom surface of a hole formed by the isotropic etching; and
etching the protective film on the bottom surface.

19. The method of manufacturing an acoustic wave device according to claim 18, wherein
the object includes an insulating layer between the second substrate and the wiring layer, a portion of the insulating layer being exposed from the through-hole; and
the method further comprises removing the insulating layer exposed from the through-hole by dry etching after the through-hole forming step.

20. The method of manufacturing an acoustic wave device according to claim 19, wherein the dry etching forms a recess in the wiring layer.

21. The method of manufacturing an acoustic wave device according to claim 20, further comprising laminating a seed layer in the recess after the dry etching.
